(19) United States
(12) Patent Application Publication
(10) Pub. No.: US 2023/0207342 A1
(43) Pub. Date: Jun. 29, 2023

(54) HOME PORT, AND APPARATUS FOR TREATING SUBSTRATE WITH THE SAME

(71) Applicant: SEMES CO., LTD., Cheonan-si (KR)

(72) Inventors: Young Jun SON, Cheonan-si (KR); Tae Hoon LEE, Osan-si (KR); Do Yeon KIM, Yongin-si (KR)

(73) Assignee: SEMES CO., LTD., Cheonan-si (KR)

(21) Appl. No.: 18/146,800

(22) Filed: Dec. 27, 2022

(30) Foreign Application Priority Data
Dec. 27, 2021 (KR) 10-2021-0189017
Sep. 27, 2022 (KR) 10-2022-0122345

(51) Int. Cl. H01L 21/67; H01L 21/687

(52) U.S. Cl. CPC H01L 21/67051; H01L 21/6715; H01L 21/67253; H01L 21/68764

(57) ABSTRACT

Provided is an apparatus for treating a substrate. The substrate treating apparatus according to an exemplary embodiment may include: a support unit supporting a substrate; a treating container covering an outer side of the support unit; a liquid supply unit including a nozzle ejecting a liquid to the substrate supported on the support unit; and a home port which is positioned outside the treating container, and in which the nozzle waits, and the home port may include a body having a discharge space to which the liquid ejected from the nozzle is discharged therein, and a measurement unit connected to the body and measuring a charging amount of the liquid discharged from the discharge space.

### CROSS-REFERENCE TO RELATED APPLICATIONS

This application claims priority to and the benefit of Korean Patent Application Nos. 10-2021-0189017 and 10-2022-0122345 filed in the Korean Intellectual Property Office on Dec. 27, 2021 and Sep. 27, 2022, the entire contents of which are incorporated herein by reference.

### TECHNICAL FIELD

The present invention relates to an apparatus for treating a substrate, and more particularly, to an apparatus for treating a substrate, which includes a home port.

### BACKGROUND ART

In order to manufacture a semiconductor device or a flat panel display panel, various processes including a photolithography process, an etching process, an ashing process, a thin-film deposition process, and a cleaning process are performed. Among the processes, in the photolithography process, a coating process of forming a coating layer on a substrate surface by supplying a photoresist on a semiconductor substrate, and an exposure process of performing exposure treating for the coating layer formed by using a mask, and then a developing process of obtaining a desired pattern on the semiconductor substrate by supplying a developing liquid are sequentially performed.

Static electricity may be generated in a facility in the process of performing the photolithography process. For example, ejection charging may occur in the process of ejecting the photoresist on the semiconductor substrate. More specifically, the photoresist may charge the semiconductor substrate, a support unit supporting the semiconductor substrate, and a treating container covering the support unit in the process of supplying the photoresist onto the semiconductor substrate. Charged objects generate induced static electricity by electrically attracting micro particles, and the induced static electricity causes a faulty of the semiconductor substrate by attracting the micro particles again. Further, the induced static electricity causes static electricity discharging to damage micro thin films and circuits formed on a high-integrated semiconductor substrate.

### SUMMARY OF THE INVENTION

An object of the present invention is to provide a home port, and an apparatus for treating a substrate with the same, which are capable of efficiently treating a substrate.

Further, an object of the present invention is to provide a home port, and an apparatus for treating a substrate with the same, which are capable of monitoring static electricity generated when ejecting a liquid.

The problem to be solved by the present invention is not limited to the above-mentioned problems, and the problems not mentioned will be clearly understood by those skilled in the art from the present specification and the accompanying drawings.

An exemplary embodiment of the present invention provides an apparatus for treating a substrate. The substrate treating apparatus according to an exemplary embodiment may include: a support unit supporting a substrate; a treating container covering an outer side of the support unit; a liquid supply unit including a nozzle ejecting a liquid to the substrate supported on the support unit; and a home port which is positioned outside the treating container, and in which the nozzle waits, and the home port may include a body having a discharge space to which the liquid ejected from the nozzle is discharged therein, and a measurement unit connected to the body and measuring a charging amount of the liquid discharged from the discharge space.

According to an exemplary embodiment, a main hole through which the liquid ejected from the nozzle passes may be formed at an upper portion of the body, and the home port may further include a partitioning plate partitioning the discharge space into a first space which is in communication with the main hole, and a second space which is in communication with the first space.

According to an exemplary embodiment, the partitioning plate may be disposed to be inclined in a falling direction of the liquid discharged from the nozzle.

According to an exemplary embodiment, an opening which makes the first space and the second space be in communication with each other is formed in the partitioning plate, and the opening is formed below a falling point of the liquid of the liquid ejected from the nozzle.

According to an exemplary embodiment, the opening may be formed in a slit shape. According to an exemplary embodiment, the opening may be at least one hole penetrating the partitioning plate.

According to an exemplary embodiment, a first discharge line to which the liquid introduced into the first space is discharged may be connected to a lower portion of the first space, and a second discharge line to which the liquid introduced into the second space is discharged through the first space may be connected to a lower portion of the second space.

According to an exemplary embodiment, the measurement unit may measure a charging amount of the liquid introduced into the second space of the first space and the second space.

According to an exemplary embodiment, each of materials of the body and the partitioning plate may include an insulating material, and surfaces of the body and the partitioning plate defining the second space may include a conductive material.

According to an exemplary embodiment, the measurement unit may be a Feraday Cup.

According to an exemplary embodiment, the measurement unit may include an accommodation unit accommodating ions or electrons included in the liquid, and a measurement unit connected to each of the surfaces of the body and the partitioning plate exposed to the second space, and measuring the charging amount of the liquid, and the accommodation unit may be the second space.

According to an exemplary embodiment, the liquid may include a photosensitive liquid or a development liquid.

Further, another exemplary embodiment of the present invention provides a home port in which a nozzle ejecting a liquid waits. According to an exemplary embodiment, the home port may include: a body having a discharge space to which the liquid ejected from the nozzle is discharged therein; a portioning plate positioned in the discharge space and partitioning the discharge space into a first space and a second space; and a measurement unit connected to the body and measuring a charging amount of the liquid discharged from the discharge space.

According to an exemplary embodiment, in the partitioning plate, a main hole which makes the outside and the first space be in fluid communication with each other may be formed at an upper portion of the body, and an opening which makes the first space and the second space be in communication with each other may be formed in the partitioning plate.

According to an exemplary embodiment, the measurement unit is electrically connected to each of the body and the partitioning plate defining the second space, and measures the charging amount of the liquid introduced into the second space.

According to an exemplary embodiment, the partitioning plate may be disposed to be inclined in a falling direction of the liquid discharged from the nozzle.

According to an exemplary embodiment, the measurement unit may be a Feraday Cup, surfaces of the body and the partitioning plate exposed to the second space may include a conductive material, the measurement unit may include an accommodation unit accommodating ions or electrons included in the liquid, and a measurement unit connected to each of the surfaces of the body and the partitioning plate exposed to the second space, and measuring the charging amount of the liquid, and the accommodation unit may be the second space.

According to an exemplary embodiment, a first discharge line to which the liquid introduced into the first space is discharged may be connected to a lower portion of the first space, and a second discharge line to which the liquid introduced into the second space is discharged through the first space may be connected to a lower portion of the second space.

Further, yet another exemplary embodiment of the present invention provides an apparatus for treating a substrate. According to an exemplary embodiment, the substrate treating apparatus may include: a housing having an internal space; a support unit supporting a substrate in the internal space; a treating container covering the support unit; a liquid supply unit including a nozzle moving between a waiting location and a process location, and ejecting a treatment liquid to the substrate; and a home port positioned outside the treating container, the nozzle may eject the treatment liquid to the substrate supported on the support unit at the process location, and the nozzle may eject the treatment liquid to the home port at the waiting location which is an upper side of the home port, and the home port may include a body having a discharge space to which the liquid ejected from the nozzle is discharged therein, and having a main hole through which the liquid ejected from the nozzle passes formed at an upper portion, a partitioning plate partitioning the discharge space into a first space which is in communication with the main hole and a second space which is in communication with the first space, and having an opening which makes the first space and the second space be in fluid communication with each other, a first discharge line connected to a lower portion of the first space and discharging the liquid introduced into the first space, a second discharge line is connected to a lower portion of the second space and discharging the liquid introduced into the second space through the opening, and a measurement unit measuring a charging amount of the liquid discharged from the second space of the first space and the second space.

According to an exemplary embodiment, the measurement unit may be provided as a Feraday Cup, surfaces of the body and the partitioning plate defining the second space may include a conductive material, the measurement unit may include an accommodation unit accommodating ions or electrons included in the liquid, and a measurement unit connected to each of the surfaces of the body and the partitioning plate exposed to the second space, and measuring the charging amount of the liquid, and the accommodation unit may be the second space.

According to an exemplary embodiment of the present invention, a substrate can be efficiently treated.

Further, according to an exemplary embodiment of the present invention, static electricity generated when ejecting a liquid can be monitored.

Further, according to an exemplary embodiment of the present invention, the static electricity by the liquid ejected from a home port which waits before performing a process is monitored to minimize ejection charging while the process is conducted.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a perspective view schematically illustrating an apparatus for treating a substrate according to an exemplary embodiment of the present invention.

FIG. 2 is a cross-sectional view schematically illustrating a coating block or a developing block of FIG. 1.

FIG. 3 is a plan view schematically illustrating the apparatus for treating a substrate of FIG. 1.

FIG. 4 is a plan view schematically illustrating a heat treating chamber according to an exemplary embodiment of the present invention.

FIG. 5 is a front view schematically illustrating a heat treating chamber according to an exemplary embodiment of the present invention.

FIG. 6 is a cross-sectional view schematically illustrating a heat treating chamber according to an exemplary embodiment of the present invention.

FIG. 7 is a plan view schematically illustrating a liquid treating chamber according to an exemplary embodiment of the present invention.

FIG. 8 is a perspective view schematically illustrating a home port according to an exemplary embodiment of the present invention.

FIG. 9 is a cross-sectional view schematically illustrating a home port according to an exemplary embodiment of the present invention.

FIG. 10 is a perspective view schematically illustrating a partitioning plate according to an exemplary embodiment of the present invention.

FIG. 11 is a diagram schematically illustrating a view in which a measurement unit measures ejection charging when a nozzle inserted into a home port ejects a liquid to the home port according to an exemplary embodiment of the present invention.

FIG. 12 is a perspective view schematically illustrating a partitioning plate according to another exemplary embodiment of the present invention.

FIGS. 13 and 14 are cross-sectional views schematically illustrating a cross-sectional view of a home port according to another exemplary embodiment.

### DETAILED DESCRIPTION

Hereinafter, an exemplary embodiment of the present invention will be described in more detail with reference to the accompanying drawings. The exemplary embodiment of the present invention can be modified in various forms, and it should not be construed that the scope of the present invention is limited to exemplary embodiments described below. The exemplary embodiment will be provided for more completely describing the present invention to those skilled in the art. Accordingly, a shape of a component in the drawing is exaggerated in order to emphasizing more clear description.

Terms including as first, second, and the like are used for describing various components, but the components should not be limited by the terms. The terms are used only for distinguishing one component from the other component. For example, a first component may be referred to as a second component, and similarly, the second component may be referred to as the first component without departing from the scope of the present invention. A substrate according to an exemplary embodiment described below is described by taking a circular substrate such as a semiconductor wafer as an example. However, the present invention is not limited thereto, and the substrate described in an exemplary embodiment of the present invention may be a rectangular substrate such as a mask or a display panel. In an exemplary embodiment of the present invention described below, a substrate treating apparatus which performs at least any one of a coating process of forming a coating layer on a substrate surface by supplying a photoresist on a semiconductor substrate, and an exposure process of performing exposure treating for the coating layer formed by using a mask, and then a developing process of obtaining a desired pattern on the semiconductor substrate by supplying a developing liquid is described as an example. However, the substrate treating apparatus is not limited to the above-described example, and the substrate treating apparatus an exemplary embodiment may be applied to various apparatuses that treat the substrate by supplying the liquid to a rotating substrate.

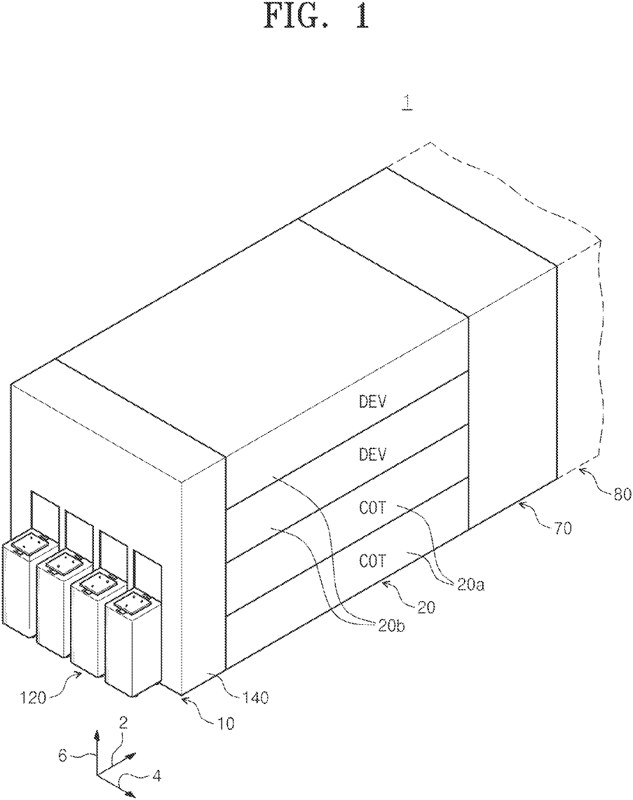

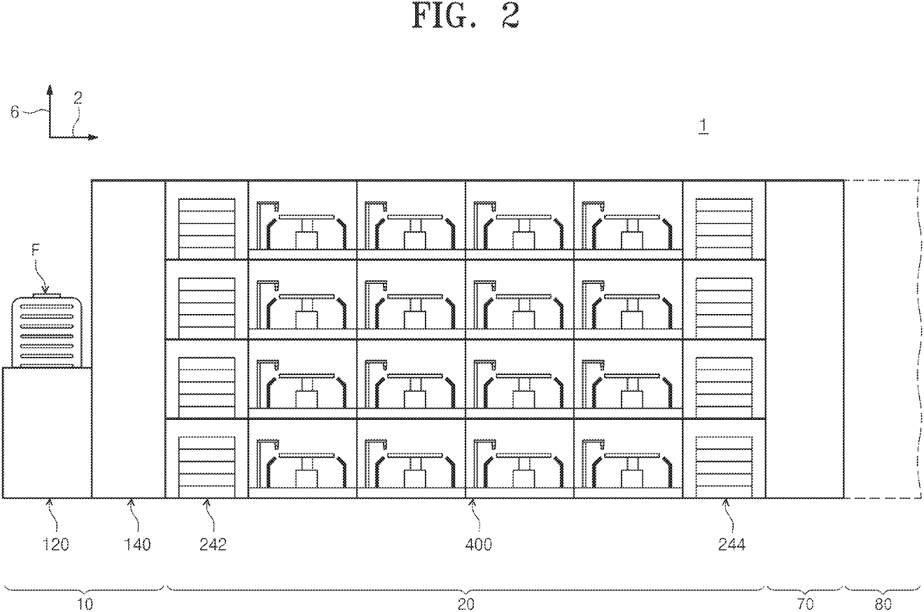

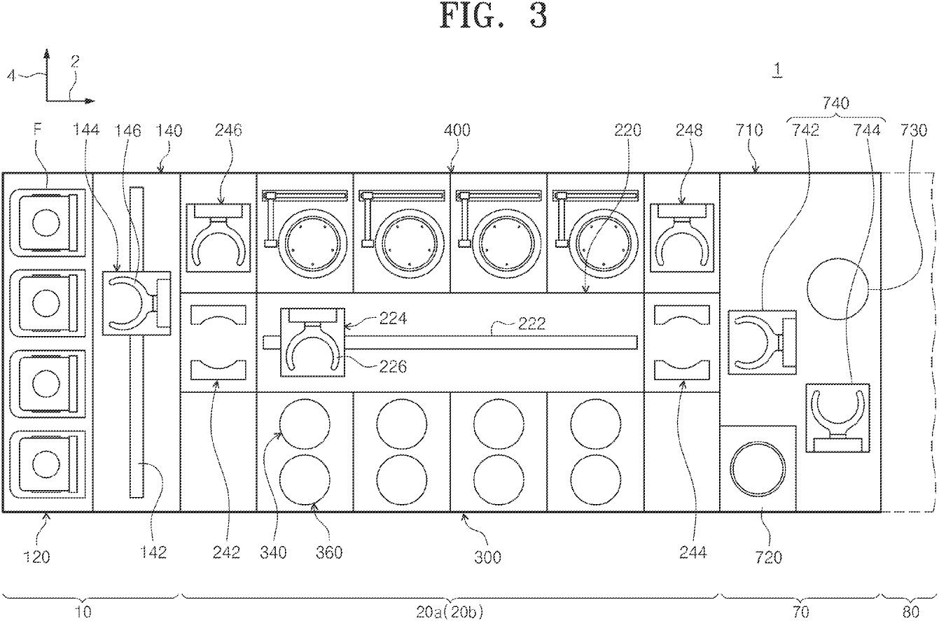

FIG. 1 is a perspective view schematically illustrating an apparatus for treating a substrate according to an exemplary embodiment of the present invention. FIG. 2 is a cross-sectional view schematically illustrating a coating block or a developing block of FIG. 1. FIG. 3 is a plan view schematically illustrating the apparatus for treating a substrate of FIG. 1.

Referring to FIGS. 1 to 3, the substrate treating apparatus 1 includes an index module 10, a treating module 20, and an interface module 70. The index module 10, the treating module 20, and the interface module 70 are sequentially arranged in line. Hereinafter, a direction in which the index module 10, the treating module 20, and the interface module 70 are arranged will be defined as a first direction 2. Further, when viewed from the top, a direction vertical to the first direction 2 is defined as a second direction 4, and a direction vertical to a plane including both the first direction 2 and the second direction 4 is defined as a third direction 6. According to an exemplary embodiment, the third direction 6 may be a direction vertical to a ground surface.

The index module 10 transfers the substrate between a container F and a treating module 20. More specifically, the index module 10 withdraws the substrate from the container F, and transfers the withdrawn substrate to the treating module 20 treating the substrate. Further, the index module 10 withdraws a substrate of which treating is completed in the treating module 20 and transfers the substrate to the container F. The index module 10 has a load port 120 and an index frame 140.

The container F storing the substrate W is accommodated in the load port 120. The load port 120 is positioned at an opposite side to the treating module 20 based on an index frame 140 to be described below. A plurality of load ports 120 may be provided, and the plurality of load ports 120 may be arranged in line in the second direction 4. The number of load ports 120 may increase or decrease according to process efficiency and a footprint condition of the treating module 20.

The container F stores the substrate. A sealing container such as a front opening unified pod (FOUP) may be used as the container F placed on the load port 120. The container F may be accommodated in the load port 120 by a transportation means or a worker such as overhead transfer, overhead conveyor, or an automatic guided vehicle.

The index frame 140 has a longitudinal direction horizontal to the second direction 4. An index rail 142 and an index robot 144 are disposed inside the index frame 140. The index rail 142 has a longitudinal direction parallel to the longitudinal direction of the index frame 140. The index robot 144 transfers the substrate. The index robot 144 may transfer the substrate between the index module 10 and a buffer chamber 240 to be described below. The index robot 144 moves in the longitudinal direction of the index rail 142 on the index rail 142. That is, the index robot 144 may move forward and backward in the second direction 4.

The index robot 144 includes an index hand 146. The substrate is placed on the index hand 146. The transfer hand 146 moves forward and backward, rotatably moves around a third direction 6 as an axis, and moves vertically in the third direction 6.

The treating module 20 may perform the coating process and the developing process for the substrate by receiving the substrate stored in the container F. According to an exemplary embodiment, the treating module 20 may have a coating block 20a and a developing block 20b. The coating block 20a performs a coating process for the substrate. The developing block 20b performs a developing process for the substrate.

A plurality of coating blocks 20a may be provided and the plurality of coating blocks 20a may be provided to be stacked on each other. Further, a plurality of developing blocks 20b may be provided and the plurality of developing blocks 20ba may be provided to be stacked on each other. Further, according to an exemplary embodiment, the coating blocks 20a may be arranged below the developing blocks 20b. Further, the respective coating blocks 20a may have the same or similar structure, and perform the same or similar process. Further, the respective developing blocks 20ba may have the same or similar structure, and perform the same or similar process. However, the coating blocks 20a are not limited thereto, and the respective coating blocks 20a may perform different processes and the respective developing blocks 20b may perform different processes. Further, the number and arrangement of coating blocks 20a, and the number of and arrangement of developing blocks 20b may be variously changed.

Since the coating block 20a and the development block 20b according to an exemplary embodiment are configured in the substantially same or similar structure and arrangement, hereinafter, the description of the development block 20b will be omitted and the coating block 20a will be described primarily.

The coating block 20a includes a transfer chamber 220, buffer chambers 242 and 244, a heat treating chamber 300, and a liquid treating chamber 400.

The transfer chamber 220 transfers the substrate among the buffer chambers 242 and 244, the heat treating chamber 300, and the liquid treating chamber 400. The transfer chamber 220 has a longitudinal direction horizontal to the first direction 2. A guide rail 222 and a transfer robot 224 having the longitudinal direction parallel to the first direction 2 are disposed. The transfer chamber 224 transfers the substrate among the buffer chambers 242 and 244, the heat treating chamber 300, and the liquid treating chamber 400. The transfer robot 224 moves linearly in the longitudinal direction of the guide rail 222 on the guide rail 222. The transfer robot 224 has the transfer hand 226 on which the substrate is placed. The transfer hand 226 moves forward and backward, rotatably moves around the third direction 6 as the axis, and elevatably moves in the third direction 6.

The buffer chambers 242 and 244 provides a space in which the substrate loaded to the coating block 20a and the substrate unloaded from the coating block 20a temporarily stay. A plurality of buffer chambers 242 and 244 may be provided. Any some of the buffer chambers are arranged between the index module 10 and the transfer chamber 220. Hereinafter, the buffer chamber will be referred to as a front buffer 242. Further, the other some of the buffer chambers are arranged between the transfer chamber 220 and the interface module 70. Hereinafter, the buffer chamber will be referred to as a rear buffer 244. A plurality of front buffers 242 is provided and arranged to be stacked on each other in the vertical direction. Further, a plurality of rear buffers 244 is provided and arranged to be stacked on each other in the vertical direction.

Each of the front buffers 242 and the rear buffers 244 temporarily keeps a plurality of substrates W. The substrate stored in the front buffer 242 is loaded or unloaded by the index robot 144 and the transfer robot 224. Further, the substrate stored in the rear buffer 244 is loaded or unloaded by the transfer robot 224 and a first robot 742 to be described below.

The buffer robots 246 and 248 may be disposed at one side of the buffer chambers 242 and 244. According to an exemplary embodiment, the front buffer robot 246 may be disposed at one side of the front buffer 242, and the rear buffer robot 248 may be disposed at one side of the rear buffer 244. However, the buffer robots are not limited thereto, and may be provided at both sides of the front buffer 242 and the rear buffer 244.

The front buffer robot 246 may transfer the substrate between the front buffers 242. The front buffer robot 246 may transfer the substrate between the front buffers 242 disposed to be stacked while moving in the third direction 6. Further, the rear buffer robot 248 may transfer the substrate between the rear buffers 244. The rear buffer robot 248 may transfer the substrate between the rear buffers 244 disposed to be stacked while moving in the third direction 6. Since the front buffer robot 246 and the rear buffer robot 248 have the substantially same or similar structure as the transfer robot 224, a detailed description thereof is omitted.

The heat treating chamber 300 performs the heat treating process for the substrate. The heat treating process according to an exemplary embodiment may a cooling process of lowering a temperature of the substrate and a heating process of raising the temperature of the substrate. A plurality of heat treating chambers 300 may be provided. The heat treating chambers 300 are arranged in the first direction 2. The heat treating chambers 300 are positioned at one side of the transfer chamber 220.

Further, the heat treating chamber 400 forms a liquid layer by supplying the liquid onto the substrate. The liquid layer according to an exemplary embodiment may be a photoresist layer or an anti-reflective layer. A plurality of heat treating chambers 400 may be provided. The liquid treating chambers 400 are arranged in the first direction 2. The liquid treating chambers 400 are arranged at one side of the transfer chamber 220. That is, the heat treating chamber 300 and the liquid treating chamber 400 are disposed to be opposite to each other based on the transfer chamber 220.

The plurality of liquid treating chambers 400 may be disposed to be stacked on each other. Further, any some of the plurality of liquid treating chambers 400 are disposed at locations adjacent to the index module 10. The liquid treating chamber 400 disposed at the location adjacent to the index module 10 may supply a first liquid onto the substrate. Further, the other some of the plurality of liquid treating chambers 400 are disposed at locations adjacent to the interface module 70. The liquid treating chamber 400 disposed at the location adjacent to the index module 70 may supply a second liquid onto the substrate. According to an exemplary embodiment, the first liquid may be the anti-reflective layer and the second liquid may be the photoresist. However, the liquids are not limited thereto, and the first liquid may be the photoresist, and the second liquid may be the anti-reflective layer. In this case, the anti-reflective layer may be supplied onto the substrate onto which the photoresist is supplied. Optionally, the first liquid and the second liquid may be the same type of liquids. In this case, the first liquid and the second liquid may be photoresists having different concentrations.

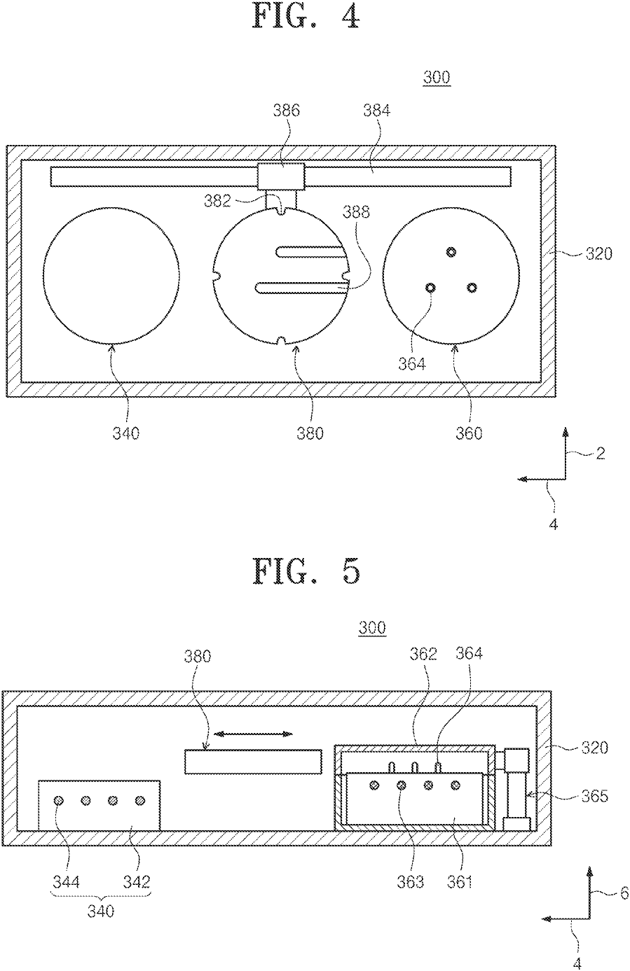

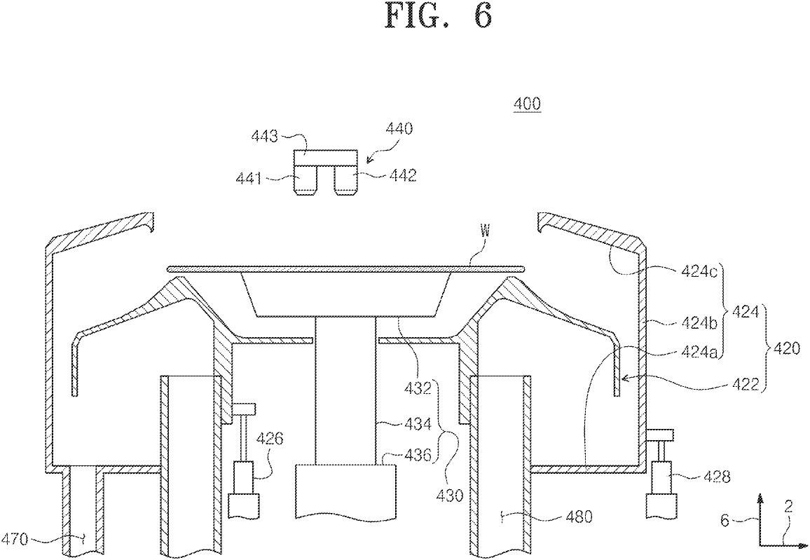

FIG. 4 is a plan view schematically illustrating a heat treating chamber according to an exemplary embodiment of the present invention. FIG. 5 is a front view schematically illustrating a heat treating chamber according to an exemplary embodiment of the present invention.

Hereinafter, the heat treating chamber according to an exemplary embodiment of the present invention will be described with reference to FIGS. 4 and 5.

The heat treating chamber 300 includes a housing 320, a cooling unit 340, a heating unit 360, and a transfer plate 380.

The housing 320 has a substantially rectangular parallelepiped shape. An entrance (not illustrated) through which the substrate enters and exits is formed on a side wall of the housing 320. The cooling unit 320, the heating unit 340, and the transfer plate 360 are positioned in the internal space of the housing 320. The cooling unit 340 and the heating unit 360 are positioned in line in the second direction 4.

According to an exemplary embodiment, the cooling unit 340 may be positioned relatively closer to the transfer chamber 220 than the heating unit 360. The cooling unit 340 includes a cooling plate 342 and a cooling flow path 344. The cooling plate 342 may have a substantially circular shape when viewed from the top. The cooling flow path 344 is positioned inside the cooling plate 342. A cooling fluid may flow in the cooling flow path 344. While the cooling fluid flows in the cooling flow path 344, the temperature of the cooling plate 342 may be lowered.

The heating unit 360 may include a heating plate 361, a cover 362, and a heater 363.

The heating plate 361 may have a substantially circular shape when viewed from the top. The heating plate 361 may have a larger diameter than the substrate. The heater 363 is disposed inside the heating plate 361. The heater 363 may be any one of known heat generation resistors generating heat by resisting to flowing current.

A plurality of lift pins 361 moving vertically in the third direction 6 are disposed on the heating plate 361. The lift pins 364 may take over the substrate from an external transfer means (e.g., the transfer plate 380) of the heating unit 360, and lay down the substrate on the heating plate 361. Further, the lift pins 364 may lift up the substrate on the heating plate 361, and hand over the substrate to the external transfer means (e.g., the transfer plate 380) of the heating unit 360.

The cover 362 has a space of which lower portion is opened. The cover 362 may be positioned at an upper side of the heating plate 361 and moved in the vertical direction by the driver 365. The driver 365 may be any one known motors capable of transmitting driving force. When the cover 362 moves downward by the driver 365, a space formed by combining the cover 362 and the heating plate 361 with each other serves as a heating space heating the substrate.

The transfer plate 380 may have a substantially disc shape. Further, the transfer plate 380 may have a diameter corresponding to the substrate. A notch 382 is formed at an edge of the transfer plate 382. Further, the transfer plate 380 may move linearly in the second direction 4. For example, the transfer plate 380 may be mounted on a guide rail 384 having a longitudinal direction horizontal to the second direction 4 via the driver 386, and linearly moved along the guide rail 384 by the driver 386. The transfer plate 380 may take over the substrate from the transfer robot 224 (see FIG. 3). Further, the transfer plate 380 may hand over the substrate to the transfer robot 224 (see FIG. 3) or the lift pin 364.

A plurality of slit-shaped guide grooves 388 is provided in the transfer plate 388. The guide groove 388 extends from an end of the transfer plate 380 to an inside of the transfer plate 380. The guide groove 388 has the longitudinal direction to the second direction, and the plurality of guide grooves 388 are formed to be spaced apart from each other in the first direction 2. The guide groove 388 may prevent the transfer plate 380 and the lift pin 364 from interfering with each other when the substrate is taken over and handed over between the transfer plate 380 and the lift pin 364.

The transfer plate 380 hands over the substrate to the lift pin 364, and the lift pin 364 moves downward to seat the substrate on the heating plate 361. The temperature of the substrate seated on the heating plate 361 may be raised by heat generation of the heater 363.

Further, the transfer plate 380 may be in contact with the cooling plate 342. More specifically, the transfer plate 380 may be in contact with the cooling plate 342 while the substrate is placed at the upper side of the transfer plate 380. The temperature of the substrate seated on the transfer plate 380 may be lowered by the cooling fluid which flows o the cooling flow path 344. The transfer plate 380 may be made a material having a high thermal conductivity so as to excellently transmit the heat between the cooling plate 342 and the substrate. According to an exemplary, the transfer plate 380 may be provided as a metallic material.

Further, according to an exemplary embodiment, the heating unit 360 provided in any some of the plurality of heat treating chambers 300 supplies to gas while heating the substrate to enhance an attachment rate of the photoresist to the substrate. According to an exemplary embodiment, the gas may be hexamethyldisilane.

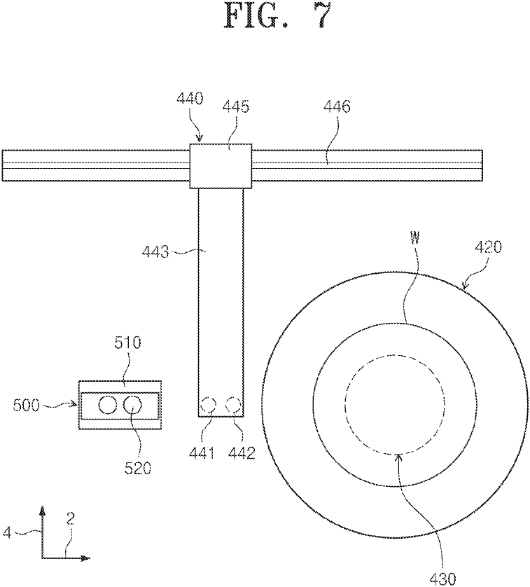

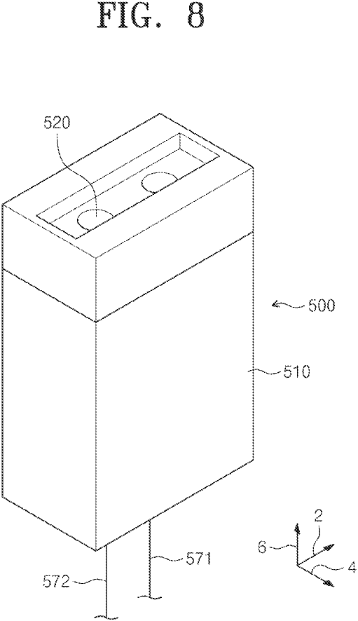

FIG. 6 is a cross-sectional view schematically illustrating a heat treating chamber according to an exemplary embodiment of the present invention. FIG. 7 is a plan view schematically illustrating a liquid treating chamber according to an exemplary embodiment of the present invention.

Hereinafter, a liquid treating chamber according to an exemplary embodiment will be described with reference to FIGS. 6 and 7.

The liquid supply unit 400 may include a treating container 420, a support unit a liquid supply unit 440, and a home port 500.

According to an exemplary embodiment, although not illustrated, a treating container 420, a support unit 430, a liquid supply unit 440, and a home port 500 may be all disposed inside the rectangular parallelepiped-shaped housing. An entrance through which the substrate enters and exits is formed on a side wall of a housing (not illustrated). Further, although not illustrated, a fan filter unit supplying air current to the inside of the housing may be installed on an upper wall of the housing (not illustrated), and a hole for exhausting an atmosphere inside the housing may be formed on a lower wall of the housing (not illustrated).

According to an exemplary embodiment, the treating container 420 may be a bowl of which upper portion is opened. The treating container 420 may have a cup shape of which upper portion is opened. The inside of the treating container 420 serves as a treating space in which the substrate W is treated. The treating space may be a space in which the support unit 430 supports and rotates the substrate W. Further, the treating space may be a space in which a liquid supply unit 440 to be described below supplies the liquid and treats the substrate W.

The treating container 420 has an inner cup 422 and an outer cup 424. The outer cup 424 may cover the inner cup 422, and the inner cup 422 may cover a part of the support unit 430. Further, the inner cup 422 may be positioned at an inner side of the outer cup 424. Each of the inner cup 422 and the outer cap 424 may have a ring shape. A space between the inner cup 422 and the outer cup 424 may serve as a recovery path in which the liquid introduced into the treating space is recovered.

The inner cup 422 may have a shape to cover a support axis 434 to be described below when viewed from the top. For example, the inner cup 422 may have a disc shape to cover the support axis 434 when viewed from the top. When viewed from the top, the inner cup 422 may be disposed to overlap with the inner cup 480. The exhaust line 480 may be coupled to a bottom wall of the housing (not illustrated), and connected to a bottom portion 424a of the outer cup 424 to be described below. A depression unit is installed in the exhaust line 480. The depression unit (not illustrated) applies a negative pressure to the treating space through the exhaust line 480 to exhaust an internal atmosphere of the treating space.

The inner cup 422 may have an inner portion and an outer portion. Top surfaces of the inner portion and the outer portion, respectively may have different angles based on a virtual horizontal line. According to an exemplary embodiment, when the inner portion is viewed form the top, the inner portion may be positioned at a region which overlaps with a body 432 to be described below. Further, as the inner portion is away from the support axis 434, the top surface may be inclined upward.

The outer portion extends outward from the inner portion. According to an exemplary embodiment, as the outer portion is away from the support axis 434, the top surface may be inclined downward. When viewed from the top, an upper end of the inner portion may be positioned to overlap with a side end of the substrate W. That is, the upper end of the inner portion may coincide with the side end of the substrate W in the vertical direction. According to an exemplary embodiment, a point where the inner portion and the outer portion meet may be a location lower than the upper end of the inner portion. Further, the point where the inner portion and the outer portion meet may be formed to be rounded. A space between the outer portion and the outer cup 424 serves as the recovery path in which the liquid is recovered.

The outer cup 424 includes the bottom portion 424a, a side portion 424b, and an inclination portion 424c. The bottom portion 424a may have a disc shape with a hollow. A recovery line 470 is connected to the bottom portion 424a. The recovery line 470 may recover the liquid supplied onto the substrate W. The liquid recovered by the recovery line 470 may be reused by an external reproduction system (not illustrated).

The side portion 424b and the inclination portion 424c may have the substantially ring shape. The side portion 424b may extend upward from the end of the bottom portion 424a. The inclination portion 424c extends from an upper end of the side portion 424b. For example, the inclination portion 424c may extend in a direction toward a central axis of the support axis 434 to be described below from the upper end of the side portion 424b. Further, the inclination portion 424c may be inclined upward toward the central axis of the support axis 434.

An inner elevation unit 426 is coupled to the inner cup 422. Further, an outer inner elevation unit 428 is coupled to the outer cup 424. The inner elevation unit 426 may elevate the inner cup 422. Further, the outer elevation unit 428 may elevate the outer cup 424. The inner elevation unit 426 and the outer elevation unit 428 may be any one of known motors transmitting the driving force. According to an exemplary embodiment, the outer elevation unit 428 may move the outer cup 424 upward while treating the substrate W. Therefore, an upper end of the inclination portion 424c may be positioned to be higher than the top surface of the substrate W supported on the support unit 430 while treating the substrate W. Contrary to this, after treating the substrate W is completed, the outer elevation unit 428 may move the outer cup 424 downward so that the upper end of the inclination portion 424c is positioned to be lower than the upper surface of the substrate W supported on the support unit 430.

The support unit 430 supports and rotates the substrate W. According to an exemplary embodiment, the support unit 430 may be a chuck that supports and rotates the substrate W. The support unit 430 may include a body 432, a support axis 434, and a driving unit 436.

The substrate W is seated on a top surface of the body 432. The top surface of the body 432 has a substantially circular shape when viewed from the top. The top surface of the body 432 has a smaller diameter than the substrate W. According to an exemplary embodiment, an adsorption hole (not illustrated) is formed at an upper portion of the body 432. The adsorption hole (not illustrated) fixes the substrate W seated on the top surface of the body 432 by a vacuum adsorption scheme. However, the present invention is not limited thereto, and support pins (not illustrated) may be disposed at the upper portion of the body 432. The support pins (not illustrated) may support the substrate by physically contacting a bottom surface and/or a side surface of the substrate.

The support axis 434 is positioned at a lower side of the body 432. The support axis 434 has a longitudinal direction horizontal to the third direction 6. The support axis 434 is coupled to the body 432. Further, the support axis 434 is coupled to the driving unit 436. The support axis 434 may rotate by receiving power from the driving unit 436. Therefore, the body 432 and the substrate seated on the body 432 may be rotated. The driving unit 436 may vary a rotational speed of the support axis 434. The driving unit 436 may be a motor that transmits the power.

The liquid supply unit 460 may supply the liquid to the substrate W supported on the support unit 440. The liquid according to an exemplary embodiment may include a coating liquid. For example, the coating liquid may be a photosensitive liquid such as a photoresist (PR) or a liquid forming the anti-reflective layer on the substrate W. However, hereinafter, a case where the photoresist is supplied to the substrate W will be described as an example for convenience of understanding.

Further, the liquid according to an exemplary embodiment may further include a pre-wet liquid. For example, the pre-wet liquid may be a liquid which may change the surface property of the substrate W. More specifically, the pre-wet liquid may be a liquid which changes the surface property of the substrate W so that the surface of the substrate W has a hydrophobic property. For example, the pre-wet liquid may be a thinner.

The liquid supply assembly 440 may include a first nozzle 441, a second nozzle 442, and an arm 443.

The first nozzle 441 supplies a first liquid to the substrate W. Further, the second nozzle 442 supplies a second liquid to the substrate W. According to an exemplary embodiment, the first liquid may be the pre-wet liquid and the second liquid may be the photoresist. However, the liquids are not limited thereto, and the first liquid may be the photoresist, and the second liquid may be the pre-wet liquid. Further, the first liquid and the second liquid may be heterogeneous liquids having concentrations. Hereinafter, for convenience of understanding, a case where the first nozzle 441 and the second nozzle 442 supply the first liquid and the second liquid to the substrate W is described as an example, but the present invention is not limited thereto. For example, the liquid supply unit 440 may include three or more nozzles.

The first nozzle 441 may supply the first liquid to the substrate W by a stream scheme. Further, the second nozzle 442 may supply the second liquid to the substrate W by the stream scheme. However, the present invention is not limited thereto, and the first nozzle 441 and the second nozzle 442 may supply the first liquid and the second liquid to the substrate W by a droop scheme.

The arm 443 supports each of the first nozzle 441 and the second nozzle 442. Each of the first nozzle 441 and the second nozzle 442 is installed at one end of the arm 443. Further, each of the first nozzle 441 and the second nozzle 442 is installed on a bottom surface of the arm 443. According to an exemplary embodiment, the first nozzle 441 and the second nozzle 442 may be detached from the arm 443.

When viewed from the top, the first nozzle 441 and the second nozzle 442 may be arranged in a direction parallel to the longitudinal direction of the rail 446 to be described below. The rail 446 may be installed on the bottom wall of the housing (not illustrated). Further, the rail 446 may be disposed at a location not to interfere with the treating container 420 and the home port 500 to be described below. The rail 446 may have a longitudinal direction parallel to the first direction 2.

The other end of the arm 443 is coupled to the driver 445. The driver 445 may be any one of known motors. The driver 445 is installed on the rail 446. The driver 445 transmits the driving force to the arm 443 to linearly move the arm 443. That is, the movement direction of the arm 443 may be guided along the rail 446 in which the driver 445 is installed. As a result, the locations of the first nozzle 441 and the second nozzle 442 installed in the arm 443 may be changed. That is, the first nozzle 441 and the second nozzle 442 may move between the process location and the waiting location by the driver 445 and the arm 443. More specifically, the process location may mean a location when the first nozzle 441 and the second nozzle 442 are at the upper side of the treating container 420. Further, the waiting location may mean a location when the first nozzle 441 and the second nozzle 442 are at the upper side of the home port 500 to be described below.

The present invention is not limited to the above-described exemplary embodiment, and the arm 443 is coupled to the rotational axis of which longitudinal direction faces the third direction 6 to swingably move, so the location of the arm 443 may be changed.

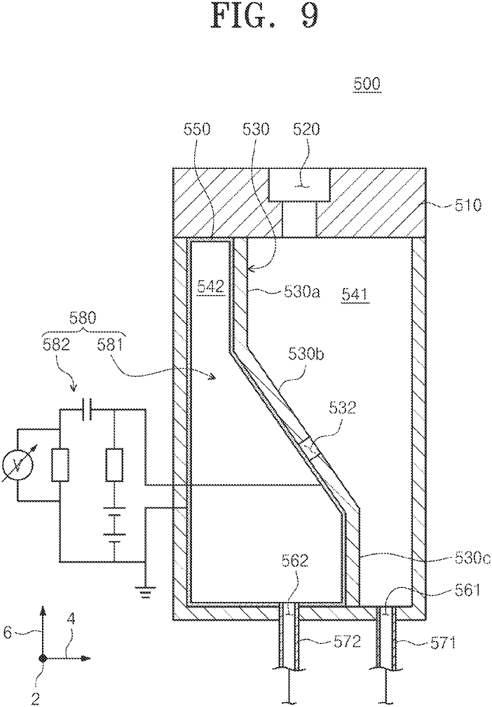

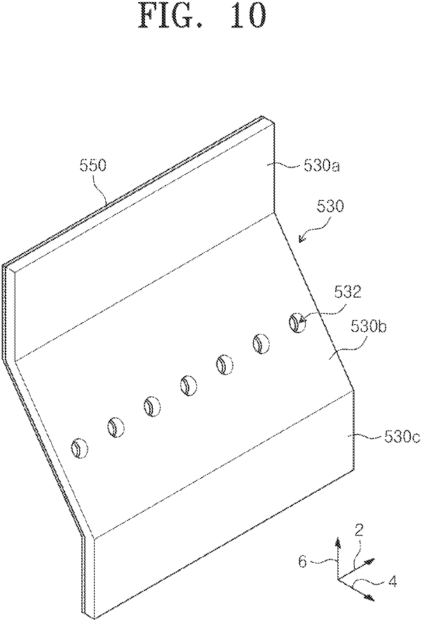

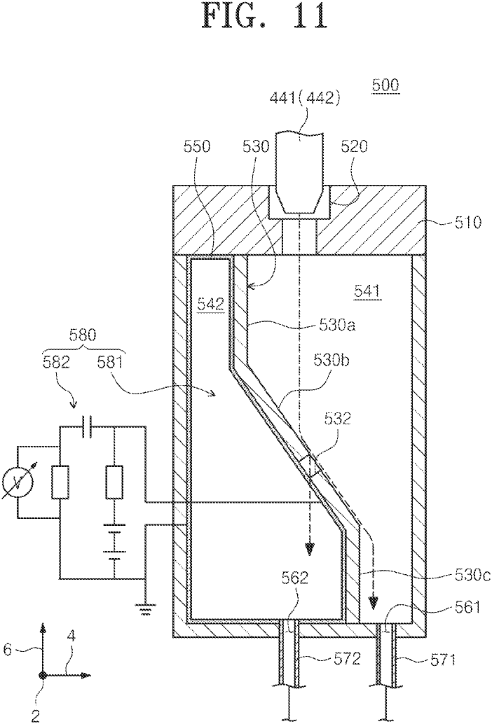

FIG. 8 is a perspective view schematically illustrating a home port according to an exemplary embodiment of the present invention. FIG. 9 is a cross-sectional view schematically illustrating a home port according to an exemplary embodiment of the present invention. FIG. 10 is a perspective view schematically illustrating a partitioning plate according to an exemplary embodiment of the present invention.

Hereinafter, a home port according to an exemplary embodiment will be described with reference to FIGS. 7 to 10. In FIGS. 7 and 8, a measurement unit according to an exemplary embodiment is not illustrated for convenience of understanding.

When the nozzles 441 and 442 do not eject the liquid onto the substrate W, the home port 500 serves as a place in which the nozzles 441 and 442 wait and are stored. When the nozzles 441 and 442 are positioned at the above-described waiting location, the nozzles 441 and 442 may continuously or intermittently eject the liquid to the home port 500. The nozzles 441 and 442 continuously or intermittently eject the liquid to the home port 500 to prevent the liquid which is accommodated or remains inside the nozzles 441 and 442 from being solidified. Further, in the home port 500, a charging amount of the liquid ejected by the nozzles 441 and 442 may be measured. A detailed description thereof will be made later.

The home port 500 may be installed on the bottom wall of the housing (not illustrated). Further, the home port 500 is disposed outside the treating container 420. The home port 500 is disposed on a movement path of the nozzles 441 and 442 which linearly move along the rail 446.

The home port 500 may include a body 510, a partitioning plate 530, and a measurement unit 580.

The body 510 may have a substantially rectangular parallelepiped shape. A material of the body 510 may include an insulating material. According to an exemplary embodiment, the material of the body 510 may include a Teflon based material. For example, the material of the body 510 may include PFA or PTFE. The body 510 may have a space therein. The internal space of the body 510 serves as a discharge space in which the liquid ejected by the nozzles 441 and 442 is discharged. A main hole 520 is formed at the upper portion of the body 510. According to an exemplary embodiment, the main hole 520 may be a through hole. The main hole 520 penetrates the discharge space inside the body 510 from the top surface of the body 510. Therefore, the main hole 520 makes the outside of the body 510 and the discharge space of the body 510 be in fluid communication with each other. More specifically, the main hole 520 makes the outside of the body 510 and a first space 541 to be described below be in fluid communication with each other.

The main hole 520 may be formed to be stepped. For example, a diameter of an upper region of the main hole 520 may be larger than a diameter of a lower region of the main hole 520. The nozzles 441 and 442 may be inserted into the upper region of the main hole 520. Therefore, the upper region of the main hole 520 serves as an insertion space into which the nozzles 441 and 442 are inserted. Further, the lower region of the main hole 520 serves as a path to which the liquid ejected by the nozzles 441 and 442 are ejected. However, the present invention is not limited thereto, and the nozzles 441 and 442 are not inserted into the main hole 520, and may eject the liquid toward the main hole 520 at the upper side of the main hole 520.

Further, a plurality of main holes 520 may be formed in the body 510. The number of main holes 520 may be provided which corresponds to the number of nozzles 441 and 442. Further, the plurality of main holes 520 may be formed in a direction horizontal to a direction win chi the nozzles 441 and 442 are arranged. For example, the plurality of main holes 520 may be formed in a direction horizontal to the first direction 2.

The partitioning plate 530 is positioned inside the body 510. The partitioning plate 530 may be formed integrally with the body 510. However, the portioning plate 530 is not limited thereto, and the partitioning plate 530 may not also be formed integrally with the body 510. Further, the material of the portioning plate 530 may include the same or similar insulating material as the material of the body 510. According to an exemplary embodiment, the material of the partitioning plate 530 may include the Teflon based material. For example, the material of the partitioning plate 530 may include PFA or PTFE. The partitioning plate 530 may have a longitudinal direction horizontal to the first direction 2 when viewed from a front surface of the home port 500. The partitioning plate 530 may be constituted by a first part 530a, a second part 530b, and a third part 530c. The first part 530a, the second part 530b, and the third part 530c are formed integrally, and are made of the same material.

The first part 530a may have a longitudinal direction horizontal to the third direction 6 when viewed from a side surface of the home port 500. A top surface of the first part 530a may be in surface-contact with the top surface of the discharge space inside the body 510. Further, both side surfaces of the first part 530a may be in surface-contact with one side surface and the other side surface of the discharge space inside the body 510, respectively. The second part 530b extends downward from the first part 530a. Further, both side surfaces of the second part 530b may be in surface-contact with one side surface and the other side surface of the discharge space inside the body 510, respectively. The second part 530b is formed to be inclined. More specifically, the second part 530b is formed to be inclined with respect to a falling direction of the liquid ejected from the nozzles 441 and 442. For example, the second part 530b may be formed to be inclined downward with respect to the ground surface toward a direction which is far away from the first part 530a. Further, the second part 530b may overlap with the main hole 520 when viewed from the top. Therefore, the liquid ejected from the nozzles 441 and 442 may fall to the second part 530b by passing through the main hole 520. That is, the liquid ejected from the nozzles 441 and 442 may fall to an inclined part of the partitioning plate 530 by passing through the main hole 520.

The third part 530cb extends downward from the second part 530b. According to an exemplary embodiment, the third part 530c may have a longitudinal direction horizontal to the third direction 6 when viewed from the side surface of the home port 500. A bottom surface of the third part 530c may be in surface-contact with the bottom surface of the discharge space inside the body 510. Further, both side surfaces of the third part 530c may be in surface-contact with one side surface and the other side surface of the discharge space inside the body 510, respectively.

As a result, the partitioning plate 530 partitions the discharge space inside the body 510. The partitioning plate 530 partitions the discharge space inside the body 510 into a first space 541 and a second space 542. The first space 541 may be a space which is in fluid communication with the main hole 520. Therefore, the liquid ejected from the nozzles 441 and 442 may be introduced into the first space 541 through the main hole 520.

Further, the second space 542 may be a space which is in fluid communication with the first space 541. Specifically, the second space 542 may be in fluid communication with the first space 541 through an opening 532 formed in the partitioning plate 530. According to an exemplary embodiment, the opening 532 may be a hole penetrating the top surface and the bottom surface of the partitioning plate 530. The opening 532 is formed in an inclined part of the partitioning plate 530. More specifically, the opening 532 is formed in a second part 530b of the partitioning plate 530, and the liquid ejected from the nozzles 441 and 442 is formed below a point where the liquid ejected from the nozzles 441 and 442 falls to the partitioning plate 530. However, the opening 532 is not limited thereto, and the opening 532 may be formed at a location which overlaps with the main hole 520 when viewed from the top. Therefore, the liquid ejected from the nozzles 441 and 442, and introduced into the first space 541 falls to the second part 530b of the partitioning plate 530, and introduced into the second space 542 via the opening 532 while flowing along an inclination surface of the second part 530b. Further, a plurality of openings 532 may be formed in the second part 530b. The plurality of openings 532 may be provided with a number larger than the number of main holes 520. However, the plurality of openings 532 are not limited, and the plurality of openings 532 may correspond to the number of main holes 520 or provided with a number smaller than the number of main holes 520.

The surfaces of the body 510 and the partitioning plate 530 may be coated. More specifically, the surface of the body 510 defining the second space 542 on the entire surface of the body 510 and the surface of the partitioning plate 530 defining the second space 542 on the entire surface of the partitioning plate 530 may be coated with a conductive material. That is, each of the surface of the body 510 exposed to the second space 542 and the surface of the partitioning plate 530 is coated with the conductive material, and a coating layer 550 may be formed on each surface. Optionally, the conductive material may be ion-injected into each of the surface of the body 510 and the surface of the partitioning plate 530. However, hereinafter, it will be described as an example that each of the surface of the body 510 and the surface of the portioning plate 530 is coated with the conductive material for convenience of understanding.

A first discharge hole 561 and a second discharge hole 562 are formed in the body 510. The first discharge hole 561 and the second discharge hole 562 are formed at the lower portion of the body 510. The first discharge hole 561 may be formed on the bottom wall of the body 510 defining the first space 541. A first discharge line 571 is connected to the first discharge hole 561. A pump applying a negative pressure (not illustrated) may be installed in the first discharge line 571. Some of the liquid introduced into the first space flows along an inclination surface (e.g., the inclination surface of the second part 530b) of the partitioning plate 530 and is introduced into the second space 542 through the opening 532, and the other some of the liquid introduced into the first space 541 is discharged to the first discharge line 571 through the first discharge hole 561.

Further, the second discharge hole 562 may be formed on the bottom wall of the body 510 defining the second space 542. A second discharge line 572 is connected to the second discharge hole 562. A pump (not illustrated) may be installed in the second discharge line 572. The pump applies the negative pressure into the second discharge line 572. The liquid introduced into the second space 542 is discharged to the second discharge line 572.

The measurement unit 580 measures the charging amount of the liquid ejected from the nozzles 441 and 442. The measurement unit 580 according to an exemplary embodiment may be a Feraday Cub. That is, the measurement unit 580 according to an exemplary embodiment may accommodate ions or electrons included in the liquid introduced into the second space 542, and measure a current amount accumulated therein.

The measurement unit 580 according to an exemplary embodiment may include an accommodation unit 581 and a measurement unit 582. The second space 542 formed by combining the body 510 and the partitioning plate 530 according to an exemplary embodiment with each other may serve as an accommodation unit of the Feraday Cup accommodating the ions or electrons. Further, the measurement unit 582 is connected to the body 510. Further, the measurement unit 582 is connected to the partitioning plate 530. More specifically, a wire of the measurement unit 582 is connected to the coating layer 550. That is, the measurement unit 582 may be electrically connected to the conductive material. According to an exemplary embodiment, any one of the wires may be electrically connected to the coating layer 550 formed on the surface of the partitioning plate 530 in the coating layer 550, and the other one may be electrically connected to the coating layer 550 formed on the surface of the body 510 in the coating layer 550. More preferably, the wire connected to the surface of the partitioning plate 530 may be electrically connected to a location adjacent to the opening 532, and a lower side than the opening 532. Therefore, the measurement unit 582 may measure the charging amount of the liquid introduced into the second space 542 serving as the accommodation unit 581 of the Feraday Cup.

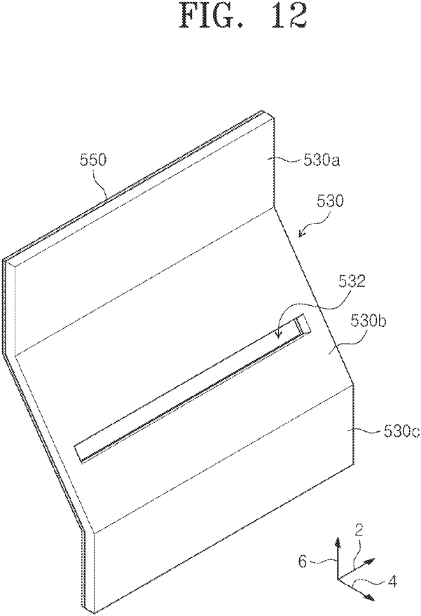

FIG. 11 is a diagram schematically illustrating a view in which a measurement unit measures ejection charging when a nozzle inserted into a home port ejects a liquid to the home port according to an exemplary embodiment of the present invention.

Referring to FIG. 11, the liquid ejected from the nozzles 441 and 442 is introduced into the first space 541. Some of the liquid introduced into the first space 541 flows along the inclination surface (e.g., the inclination surface of the second part 530b) of the partitioning plate 530, and is introduced into the second space 542 serving as the accommodation unit 581 of the Feraday Cup by passing through the opening 532 in this process. While the liquid passes through the opening 532, and is discharged through the second discharge line 572, the liquid may be in contact with the coating layer 550 in the second space 542. The wires of the measurement unit 582 connected to the coating layer 550 measure the current amount from the ions or electrons introduced into the second space 542 to measure and monitor the charging amount of the liquid ejected by the nozzles 441 and 442. Therefore, the measurement unit 580 may constantly monitor a quantitative value of static electricity generated when the nozzles 441 and 442 eject the liquid. As a result, when the nozzles 441 and 442 perform the process at the process location, ejection charging occurs in the substrate W by the liquid ejected from the nozzles 441 and 442 to prevent induced static electricity from being generated.

That is, according to an exemplary embodiment of the present invention, the partitioning plate 530 may partition the internal discharge space of the body 510 into the first space 541 and the second space 542, and utilizes the second space 542 as the accommodation unit of the Feraday Cup that measures and monitors the charging amount of the liquid to minimize a structural complexity of the home port, and simultaneously, measure and monitor the ejection charging of the liquid in the home port.

In the above-described exemplary embodiment, it is described as an example that the main hole 520 is the through hole, but the main hole 520 is not limited thereto. For example, the main hole 520 has a slit shape.

Hereinafter, a modified exemplary embodiment of the present invention will be described. Except for a case where exemplary embodiments described below are additionally described, since the exemplary embodiment is the same as or similar to an exemplary embodiment of the present invention described above, a description of duplicated contents is omitted.

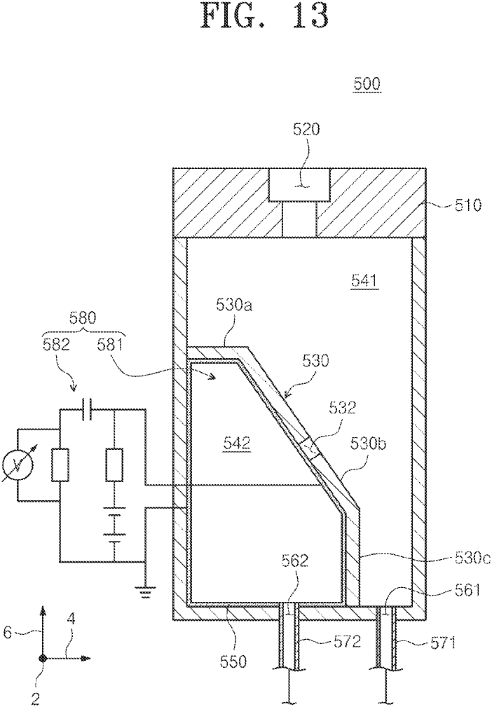

FIG. 12 is a perspective view schematically illustrating a partitioning plate according to another exemplary embodiment of the present invention.

Referring to FIG. 12, the opening formed in the partitioning plate 530 may have the slit shape. The longitudinal direction of the slit-shaped opening 532 may be horizontal to the first direction 2. When the slit-shaped opening 532 is viewed from the top, the slit-shaped opening 532 may be formed at the location which overlaps with the main hole 520 (see FIG. 8).

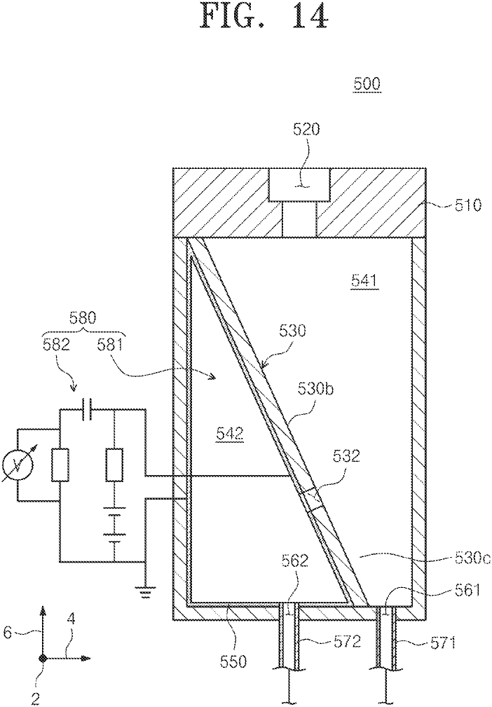

FIGS. 13 and 14 are cross-sectional views schematically illustrating a cross-sectional view of a home port according to another exemplary embodiment.

Referring to FIG. 13, the partitioning plate 530 may be constituted by a first part 530a, a second part 530b, and a third part 530c. The second part 530b and the third part 530c according to an exemplary embodiment have the same or similar as or to the above-described example, so the first part 530a will be described below.

A top surface of the first part 530a is positioned at the lower side from the top surface of the internal discharge space of the body 510. The top surface of the first part 530a is disposed to be spaced apart from the top surface of the discharge space of the body 510. The first part 530a may have a longitudinal direction horizontal to the second direction 4 when viewed from the side surface of the home port 500.

According to an exemplary embodiment of the present invention described above, the first space 541 may have a relatively larger area than the second space 542. For convenience of understanding, unlike FIG. 13 illustrated, the second space 542 may be configured to have a very small area. Therefore, the liquid may more frequently contact the surface of the body 510 defining the second space 542, and the surface of the partitioning plate 530. Consequently, the measurement unit 580 (see FIG. 9) may more precisely measure the charging amount of the liquid.

Referring to FIG. 14, according to an exemplary embodiment of the present invention, the partitioning plate 530 may be constituted by the inclination portion 530b. That is, an entire area of the partitioning plate 530 may be formed to be inclined.

Referring back to FIGS. 1 to 3, the interface module 70 connects the treating module 20 and an external exposure apparatus 80. The interface module 70 includes an interface frame 710, an additional process chamber 720, an interface buffer 730, and a transfer unit 740.

The additional process chamber 720, the interface buffer 730, and the transfer unit 740 are disposed in the internal space of the interface frame 710. The additional process chamber 720 may perform a predetermined additional process before the substrate of which predetermined process is completed in the coating block 20a is carried in the exposure apparatus 80. Optionally, the additional process chamber 720 may perform a predetermined additional process before the substrate of which process is completed in the exposure apparatus 80 is carried in the developing block 20b. The additional process according to an exemplary embodiment may include an edge exposure process of exposing an edge region of the substrate, a top surface cleaning process of cleaning the top surface of the substrate, or a cleaning process of the bottom surface of the substrate.

A plurality of additional process chambers 720 may be provided. Further, the plurality of additional process chambers 720 may be disposed to be stacked on each other. All of the additional process chambers 720 may perform the same process. Optionally, the additional process chambers 720 may perform different processes.

The interface buffer 730 provides a space in which the substrate is temporarily stays in the process of transferring the substrate among the coating block 20a, the additional process chamber 720, the exposure apparatus 80, and the developing block 20b. A plurality of interface buffers 730 may be provided and the plurality of interface buffers 730 may be provided to be stacked on each other.

The transfer unit 740 transfers the substrate among the coating block 20a, the additional process chamber 720, the exposure apparatus 80, and the developing block 20b. The transfer unit 740 includes at least one robot. According to an exemplary embodiment, the transfer unit 740 may include a first robot 742, a second robot 744, and a third robot (not illustrated). The first robot 742 may transfer the substrate among the coating block 20a, the additional process chamber 720, and the exposure apparatus 80. More specifically, the first robot 742 may transfer the substrate among the rear buffer 244, the additional process chamber 720, and the exposure apparatus 80. Further, the second robot 744 may transfer the substrate between the interface buffer 730 and the exposure apparatus 80. The third robot not illustrated may transfer the substrate between the interface buffer 730 and the development block 20b. Each of the first robot 742, the second robot 744, and the third robot not illustrated may include a hand in which the substrate is placed. Each hand may move forward and backward, rotatably move around an axis parallel to the third direction 6, and vertically move in the third direction 6.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed embodiment. Further, the accompanying claims should be construed to include other exemplary embodiments as well.

What is claimed is:

1. An apparatus for treating a substrate, the apparatus comprising:
a support unit supporting a substrate;
a treating container covering an outer side of the support unit;
a liquid supply unit including a nozzle ejecting a liquid to the substrate supported on the support unit; and
a home port which is positioned outside the treating container, and in which the nozzle waits,
wherein the home port includes
a body having a discharge space to which the liquid ejected from the nozzle is discharged therein, and
a measurement unit connected to the body and measuring a charging amount of the liquid discharged from the discharge space.

2. The apparatus of claim 1, wherein a main hole through which the liquid ejected from the nozzle passes is formed at an upper portion of the body, and
the home port further includes a partitioning plate partitioning the discharge space into a first space which is in communication with the main hole, and a second space which is in communication with the first space.

3. The apparatus of claim 2, wherein the partitioning plate is disposed to be inclined in a falling direction of the liquid discharged from the nozzle.

4. The apparatus of claim 3, wherein an opening which makes the first space and the second space be in communication with each other is formed in the partitioning plate, and
the opening is formed below a falling point of the liquid of the liquid ejected from the nozzle.

5. The apparatus of claim 4, wherein the opening is formed in a slit shape.

6. The apparatus of claim 4, wherein the opening is at least one hole penetrating the partitioning plate.

7. The apparatus of claim 2, wherein a first discharge line to which the liquid introduced into the first space is discharged is connected to a lower portion of the first space, and
a second discharge line to which the liquid introduced into the second space is discharged through the first space is connected to a lower portion of the second space.

8. The apparatus of claim 2, wherein the measurement unit measures a charging amount of the liquid introduced into the second space of the first space and the second space.

9. The apparatus of claim 8, wherein each of materials of the body and the partitioning plate includes an insulating material, and
surfaces of the body and the partitioning plate defining the second space include a conductive material.

10. The apparatus of claim 9, wherein the measurement unit is a Feraday Cup.

11. The apparatus of claim 10, wherein the measurement unit includes an accommodation unit accommodating ions or electrons included in the liquid, and a measurement unit connected to each of the surfaces of the body and the partitioning plate exposed to the second space, and measuring the charging amount of the liquid, and
the accommodation unit is the second space.

12. The apparatus of claim 1, wherein the liquid includes a photosensitive liquid or a development liquid.

13. A home port in which a nozzle ejecting a liquid waits, the home port comprising:
a body having a discharge space to which the liquid ejected from the nozzle is discharged therein;
a portioning plate positioned in the discharge space and partitioning the discharge space into a first space and a second space; and
a measurement unit connected to the body and measuring a charging amount of the liquid discharged from the discharge space.

14. The home port of claim 13, wherein in the partitioning plate, a main hole which makes the outside and the first space be in fluid communication with each other is formed at an upper portion of the body, and
an opening which makes the first space and the second space be in communication with each other is formed in the partitioning plate.

15. The home port of claim 14, wherein the measurement unit is electrically connected to each of the body and the partitioning plate defining the second space, and measures the charging amount of the liquid introduced into the second space.

16. The home port of claim 15, wherein the partitioning plate is disposed to be inclined in a falling direction of the liquid discharged from the nozzle.

17. The home port of claim 13, wherein the measurement unit is a Feraday Cup,
surfaces of the body and the partitioning plate exposed to the second space include a conductive material,
the measurement unit includes an accommodation unit accommodating ions or electrons included in the liquid, and a measurement unit connected to each of the surfaces of the body and the partitioning plate exposed to the second space, and measuring the charging amount of the liquid, and
the accommodation unit is the second space.

18. The home port of claim 13, wherein a first discharge line to which the liquid introduced into the first space is discharged is connected to a lower portion of the first space, and
a second discharge line to which the liquid introduced into the second space is discharged through the first space is connected to a lower portion of the second space.

19. An apparatus for treating a substrate, the apparatus comprising:
a housing having an internal space;
a support unit supporting a substrate in the internal space;
a treating container covering the support unit;
a liquid supply unit including a nozzle moving between a waiting location and a process location, and ejecting a treatment liquid to the substrate; and
a home port positioned outside the treating container,
wherein the nozzle ejects the treatment liquid to the substrate supported on the support unit at the process location, and
the nozzle ejects the treatment liquid to the home port at the waiting location which is an upper side of the home port, and
the home port includes
a body having a discharge space to which the liquid ejected from the nozzle is discharged therein, and having a main hole through which the liquid ejected from the nozzle passes formed at an upper portion,
a partitioning plate partitioning the discharge space into a first space which is in communication with the main hole and a second space which is in communication with the first space, and having an opening which makes the first space and the second space be in fluid communication with each other,
a first discharge line connected to a lower portion of the first space and discharging the liquid introduced into the first space,
a second discharge line is connected to a lower portion of the second space and discharging the liquid introduced into the second space through the opening, and a measurement unit measuring a charging amount of the liquid discharged from the second space of the first space and the second space.

20. The apparatus of claim 19, wherein the measurement unit is provided as a Feraday Cup,
surfaces of the body and the partitioning plate defining the second space include a conductive material,
the measurement unit includes an accommodation unit accommodating ions or electrons included in the liquid, and a measurement unit connected to each of the surfaces of the body and the partitioning plate exposed to the second space, and measuring the charging amount of the liquid, and
the accommodation unit is the second space.
